(19) United States
(12) Patent Application Publication
(10) Pub. No.: US 2024/0133206 A1
(43) Pub. Date: Apr. 25, 2024

(54) LATCH MECHANISM FOR AN ENCLOSURE

(71) Applicant: Panduit Corp., Tinley Park, IL (US)

(72) Inventor: David J. Papesh, Joliet, IL (US)

(73) Assignee: Panduit Corp., Tinley Park, IL (US)

(21) Appl. No.: 17/970,977

(22) Filed: Oct. 20, 2022

(51) Int. Cl. E05B 9/08; E05C 3/12; E05C 7/02

(52) U.S. Cl. CPC E05B 9/08; E05C 3/12; E05C 7/02

(57) ABSTRACT

An enclosure used to mount electrical equipment. The enclosure includes a wall mount section, a center section pivotally attached to the wall mount section along one side, and a latch mechanism securing the opposite side of the center section to the wall mount section. The latch mechanism is accessible only from the front of the enclosure. The latch mechanism has a front latch support, a rear latch support, a cam latch, and an actuation rod. The actuation rod extends through the front latch support and the rear latch support and is secured to the cam latch. The latch mechanism secures the wall mount section to the center section.

### FIELD OF THE INVENTION

The present invention relates to an enclosure, and more particularly to the latch mechanism for providing security to an enclosure and latching two sections of the enclosure together.

### BACKGROUND OF THE INVENTION

Dual hinged wall mount electrical enclosures are used in many industrial, enterprise, and data center applications for network access and distribution frames. As illustrated in FIGS. 1-5, the wall mount enclosure 20 is composed of a wall mount section 22, a center section 24, and a front door 28. The center section 24 is hinged to the wall mount section 22, and the front door 28 is hinged to the front of the center section 24. The front door 28 is secured in a closed position by locks 30. As illustrated in FIGS. 3A and 3B, the center section 24 is internally latched to the wall mount section 22. The internal latch 40 includes a handle 42 that remains vertical in the latched position. As illustrated in FIG. 5, the wall mount section 22 may be unlatched and may pivot with respect to the center section 24, when desired.

Security for the network is important in these applications requiring locking latches, tamper proof latches and electronic access to protect the network connections and the network electronic devices such as switches, servers, and UPS. A challenge for latching the center section to the wall mount section has been limiting access to the latch. Prior enclosures have attempted to provide latching however, the latches have disadvantages. The prior enclosures utilizing exterior knobs, latches, locking cams, or padlocks limiting security. The prior latch mechanisms on enclosures occupy space exterior to the enclosure that has limited access due to the enclosure placement next to existing building infrastructure or devices. Prior enclosures also may have handles that actuate a latch mechanism and interfere with the rack unit space for rack mounted equipment. As illustrated in FIGS. 4A and 4B, the handle 42 is rotated to release the latch 40 securing the center section 24 to the wall mount section 22. However, in the unlatched position, the horizontal handle 42 would interfere with the equipment mounted to the rails in the enclosure 20. As a result, these prior art latch mechanisms limit where the devices can be placed in a rack and force the network engineer to be cautious of where he is placing his equipment.

As a result, it is desirable to provide an enclosure with a new latch mechanism that provides security to the enclosure while not interfering with the equipment mounted within the enclosure.

### SUMMARY OF THE INVENTION

The present invention is directed to an enclosure for mounting electrical equipment. The enclosure includes a wall mount section, a center section and a latch mechanism that secures the center section to the wall mount section. The center section is pivotally attached to the wall mount section along one side. The latch mechanism secures the opposite side of the wall mount section to the center section. The latch mechanism is accessible only at a front of the enclosure. The latch mechanism has a front latch support, a rear latch support, a cam latch, and an actuation rod. The actuation rod extends through the front latch support, the rear latch support, and the cam latch. The actuation rod is further secured to the cam latch to enable the latch mechanism to latch the wall mount section to the center section.

### BRIEF DESCRIPTION OF THE DRAWINGS

FIG. 1 is a right perspective view of a prior art of a wall mount enclosure.

FIG. 2 is a left perspective view of the prior art wall mount enclosure of FIG. 1.

FIG. 3A is a perspective view of the prior art wall mount enclosure of FIG. 2 with the wall mount section secured to the center section and with the front door open and the top partially removed.

FIG. 3B is a front view of the prior art wall mount enclosure of FIG. 3A.

FIG. 4A is a perspective view of the prior art wall mount enclosure of FIG. 2 with the wall mount section unlatched from the center section and with the front door open and the top partially removed.

FIG. 4B is a front view of the prior art wall mount enclosure of FIG. 4A.

FIG. 5 is a perspective view of the prior art wall mount enclosure of FIG. 2 with the wall mount section unlatch from the center section.

FIG. 6A is a perspective view of a wall mount enclosure with the front door removed and the latch mechanism of the present invention.

FIG. 6B is a perspective view of the wall mount enclosure of FIG. 6A with a tool positioned to rotate the latch mechanism of the present invention.

FIG. 7A is a perspective view of the wall mount enclosure of FIG. 6A with the latch mechanism rotated to unlatch the wall mount section from the center section.

FIG. 7B is a perspective view of the wall mount enclosure of FIG. 7A with the tool removed from the latch mechanism.

FIG. 8 is a perspective view of the latch mechanism securing the wall mount section and the center section of FIG. 6A.

FIG. 9 is a cross sectional view of the latch mechanism taken along line 9-9 of FIG. 8.

FIG. 10 is a cross sectional view of the latch mechanism taken along line 10-10 of FIG. 8.

FIG. 11A is a perspective view of the latch mechanism of FIG. 6A in a locked position.

FIG. 11B is a perspective view of the latch mechanism of FIG. 6A in an unlocked position.

FIG. 12 is a partially exploded view of the latch mechanism of FIG. 11B.

### DETAILED DESCRIPTION

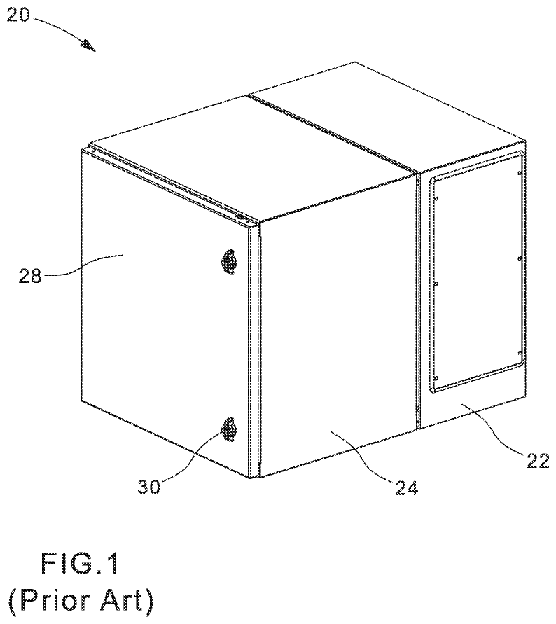

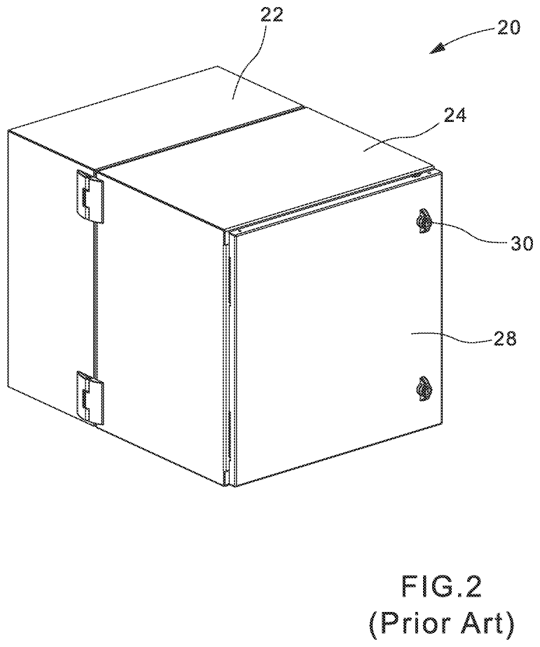

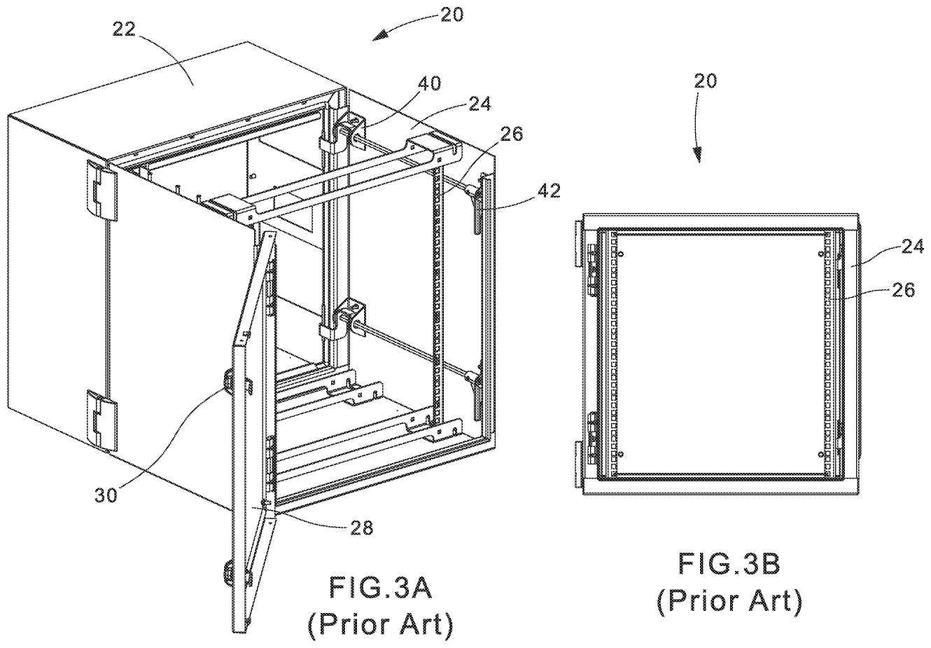

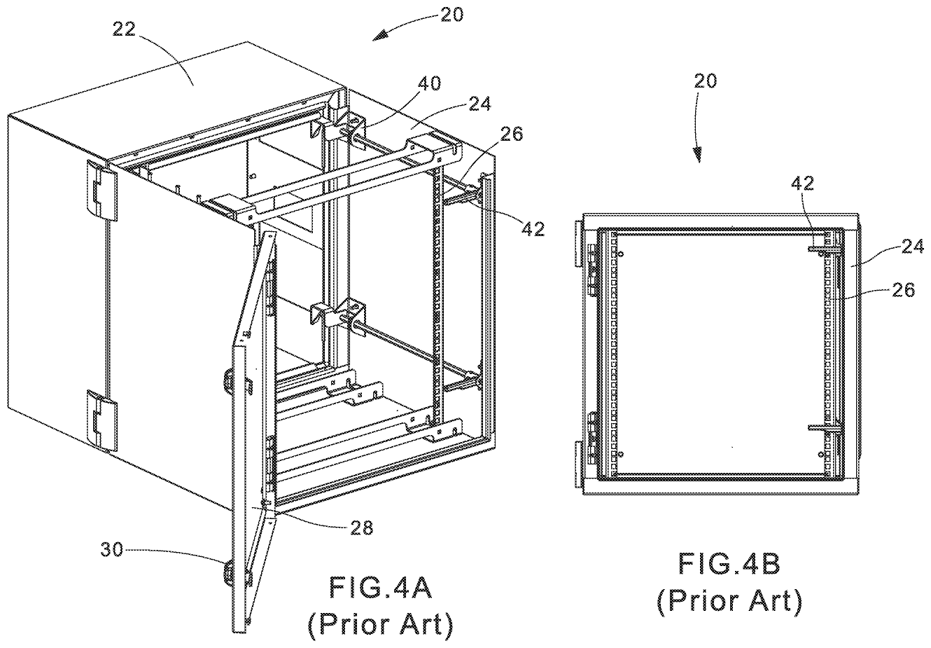

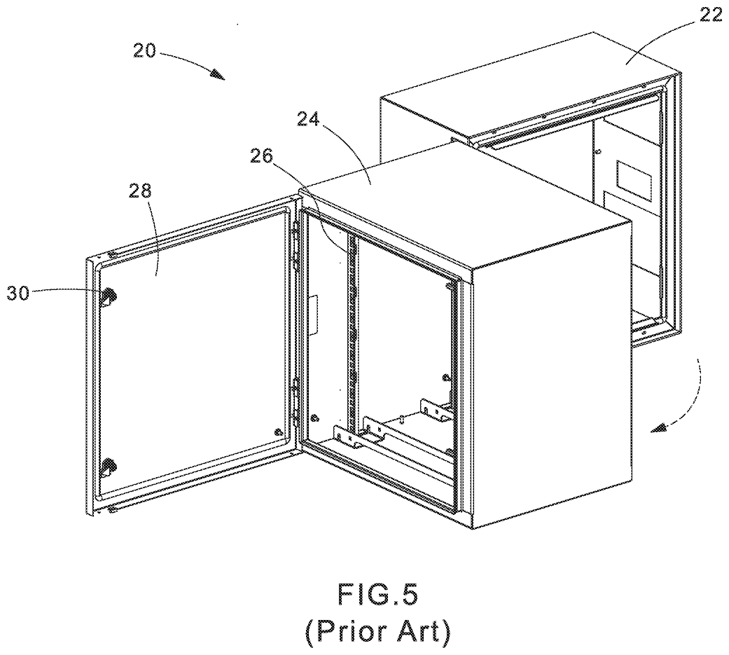

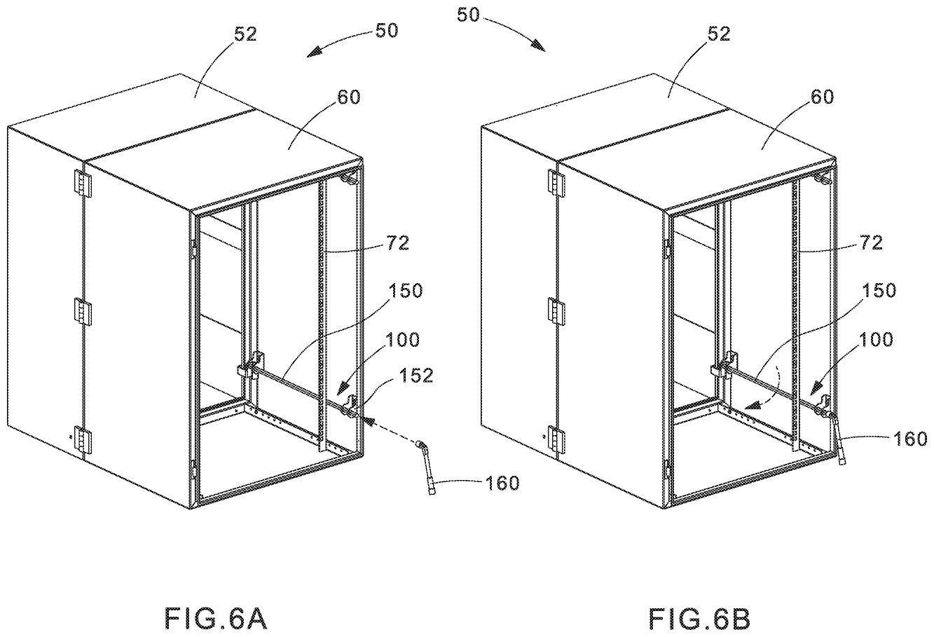

FIGS. 6A and 6B illustrate a wall mount enclosure 50 with the front door removed for clarity. The wall mount enclosure 50 includes a wall mount section 52, a center section 60 hinged to the wall mount section 52 along one side, and a front door (not illustrated). The front door is hinged to the center section 60 along one side as shown with respect to prior art FIGS. 1-5. The wall mount section 52 is latched to the center section 60 by the latch mechanism 100 of the present invention. The latch mechanism 100 is designed to be actuated from the front of the enclosure 50 without encroaching upon the network equipment installed inside the enclosure 50. Actuation of the latch mechanism 100 occurs outside the center section 60. As illustrated in FIG. 6A, a distal end 152 of the actuating rod 150 is exposed outside the center section 60 for easy access. A temporary handle 160, such as a socket wrench or a standard open box wrench, is positioned to engage the distal end 152 of the actuation rod 150. As illustrated in FIG. 6B, the socket wrench 160 is positioned on the distal end 152 of the actuating rod 150.

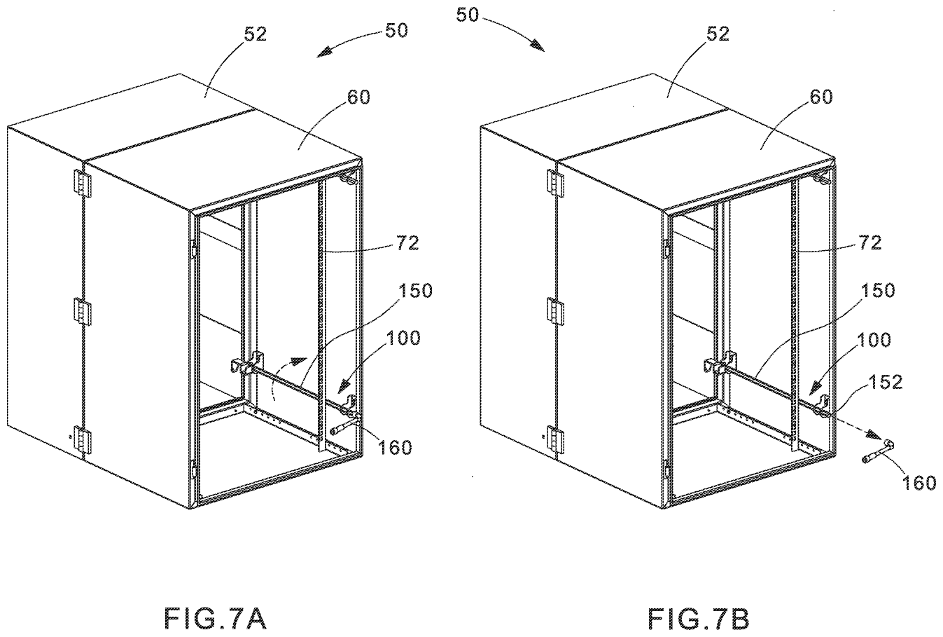

FIGS. 7A and 7B illustrate the latch mechanism 100 including the attached actuation rod 150 rotated to unlatch the center section 60 from the wall mount section 52. Once the actuation rod 150 has been rotated and the wall mount section 52 and center section 60 have been unlatched, the socket wrench 160 may be removed from the distal end 152 of the actuation rod 150.

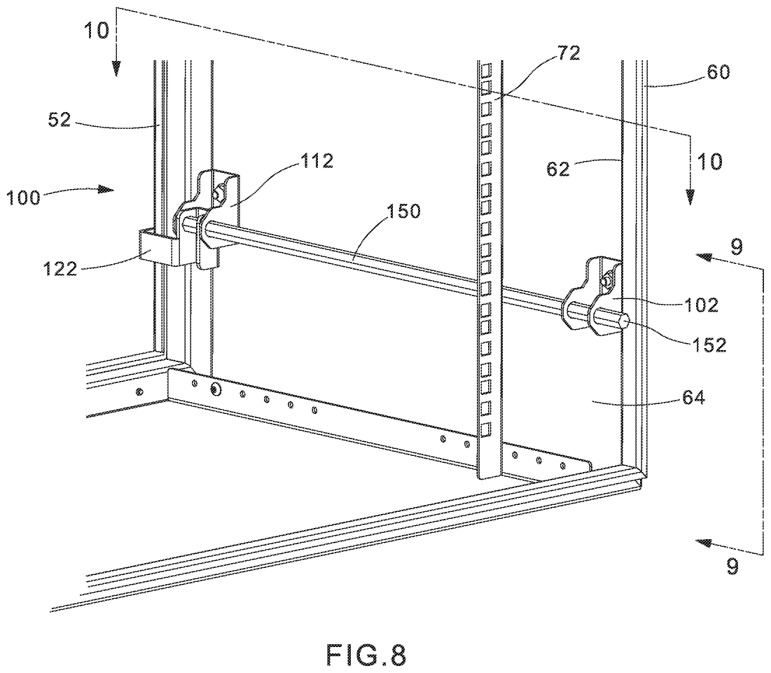

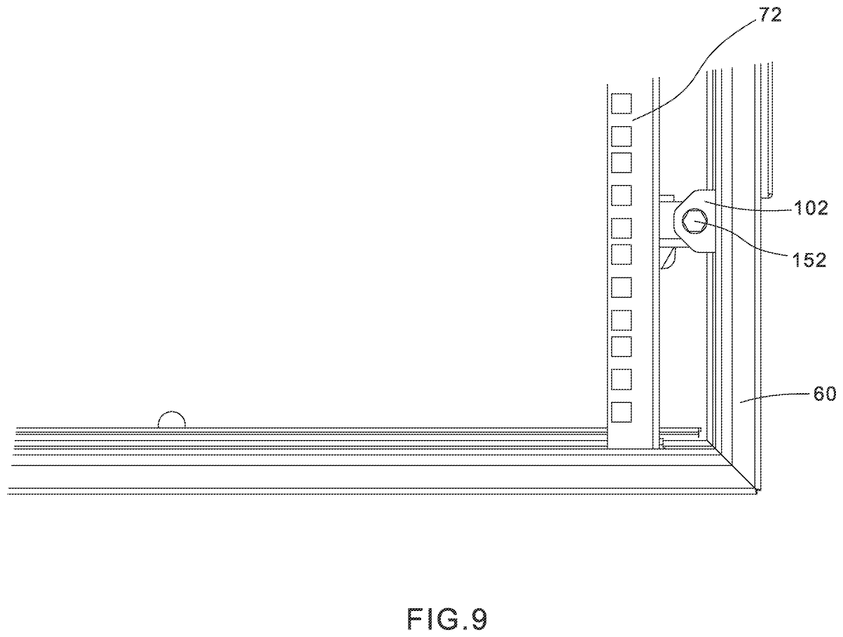

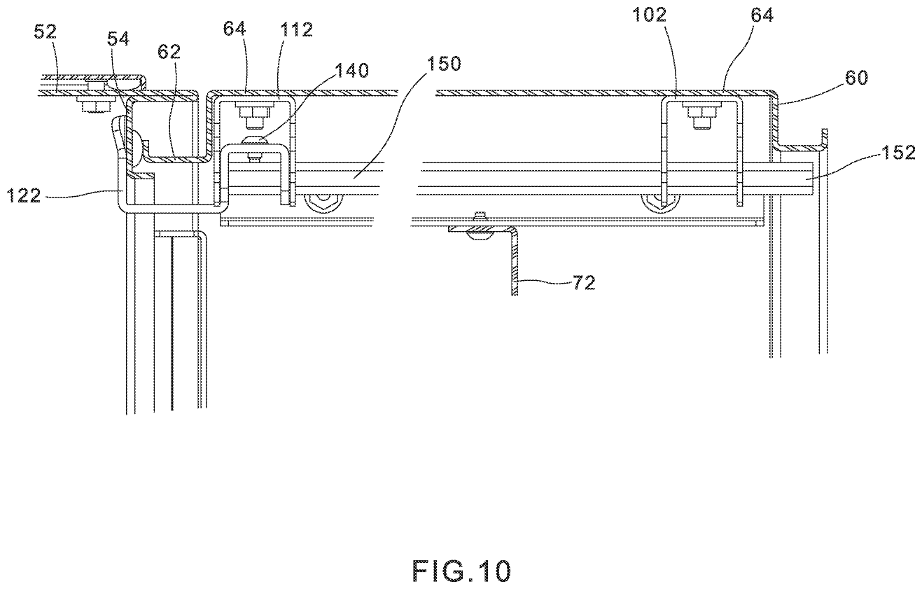

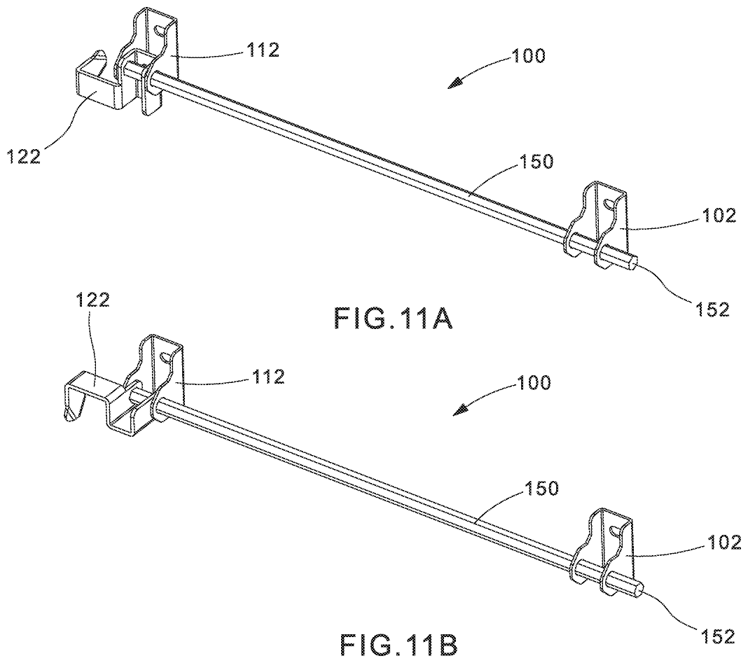

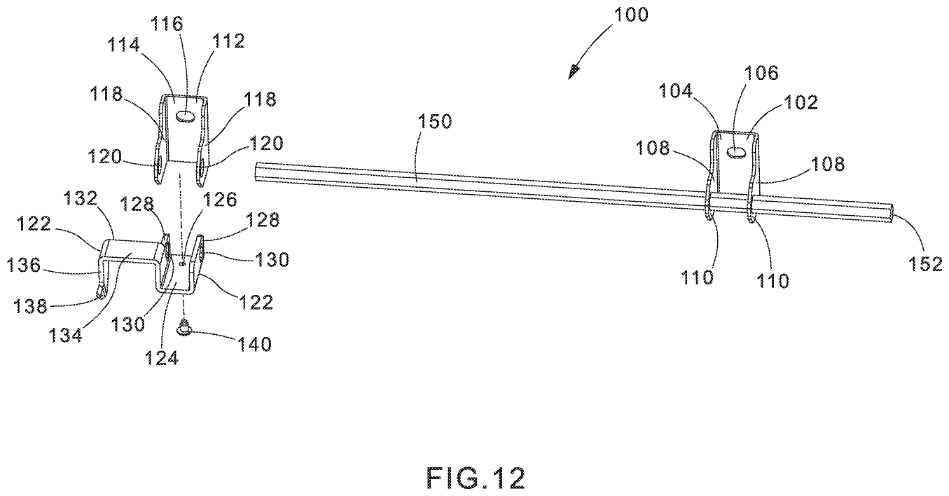

As illustrated in FIGS. 8-12, the latch mechanism 100 includes an actuation rod 150, a front latch support 102, a rear latch support 112, a cam latch 122, and a screw 140. The front and rear latch supports 102, 112, respectively, include a base 104, 114 with arms 108, 118 extending from the side edges of the base 104, 114. The base 104 of the front latch support 102 includes a mount opening 106 for receiving a fastener to secure the front latch support 102. The base 114 of the rear latch support 112 includes a mount opening 116 for receiving a fastener to secure the rear latch support 112. As illustrated in FIGS. 8 and 10, the front latch support 102 and the rear latch support 112 are mounted via a fastener to the inside side wall 64 of the center section 60 of the enclosure 50. The arms 108 of the front latch support 102 and the arms 118 of the rear latch support 112 include rod openings 110, 120, respectively, for receiving the actuation rod 150. The front latch support 102 and the rear latch support 112 are positioned and mounted to the center section 60 such that the arms 108, 118 do not interfere with the inner flanges 62 of the center section 60, the equipment rail 72 or equipment that would be mounted therein.

The cam latch 122 includes a base 124 with arms 128 that extend from the side edge of the base 124. The base 124 includes a mounting opening 126 for receiving a screw 140. The arms 128 include rod openings 130 for receiving the actuation rod 150 similar to the rod openings 110, 120 in the arms 108, 118 of the front and rear latch supports 102, 112, respectively. The cam latch 122 also includes a L shaped connector 132 that extends from one of the arms 128 of the cam latch 122. The L shaped connector 132 has a first member 134 that is parallel to the base 124 of the cam latch 122 and a second member 136 that is parallel to the arms 128 of the cam latch 122. The L-shaped connector 132 also includes a curved flange 138 extending from an edge of the second member 136.

The cam latch 122 is mounted between the arms 118 of the rear latch support 112 to prevent the cam latch 122 from moving out of position. The rod openings 130 in the arms 128 of the cam latch 122 align with the rod openings 120 in the arms 118 of the rear latch support 112. The actuation rod 150 extends from the front opening of the enclosure 50 through the rod openings 110 in the arms 108 of the front latch support 102 and through the rod openings 130 in the arms 128 of the cam latch 122 and the rod openings 120 in the arms 118 of the rear latch support 112. A screw 140 secures the actuation rod 150 to the base 124 of the cam latch 122.

As described above, the actuation rod 150 is rotated utilizing a temporary handle 160 such as a standard open box wrench or socket wrench. No special handle is required to activate the actuation rod 150 to rotate the cam latch 122 that engages the center section 60 and the wall mount section 52 to hold the sections together. The actuation rod 150 is forward of any network equipment rails 72 and network equipment there by eliminating interference of the rack unit space by the temporary handle 160. FIGS. 8-10 illustrate the position of the actuation rod 150 and the remainder of the latch mechanism 100 with respect to the equipment rail 72 in the enclosure.

The latch mechanism 100 can only be actuated at the front of the enclosure when the front door is open. The temporary handle 160, such as a standard open box wrench or a socket wrench is positioned outside of the front of the center section 60. Concealing the latch mechanism 100 behind the front door provides a level of access security for the enclosure components preventing access to the wall mount section 52 without entering the front door. Some prior enclosures have a latch activated external to the enclosure limiting the amount of security for entering the rear of the enclosure. Other prior enclosures, such as shown in FIGS. 1-5, have the same type of security as the current invention but interfere with the rack unit space for rack mounted equipment limiting where equipment may be placed. As with the prior art front doors of enclosures, the front door can only be opened using a keyed entry latch or padlock latch thereby providing access security for the network equipment or electronics inside the enclosure.

The cam latch 122 is mounted to be positioned around the center section 60 and to clamp against the inside of the wall mount section flange 54 (see FIG. 10). Rotating the actuator rod 150 engages the cam latch 122 against the inner wall of the wall mount section 52 drawing the center section 60 and the wall mount section 52 together. FIGS. 8-10 show the cam latch 122 in the closed position. Rotating the actuation rod 150 in the opposite direction disengages the wall mount section 52 from the center section 60 allowing the wall mount section 52 and the center section 60 to rotate with respect to each other.

The design of the latch mechanism 100 of the present invention allows the user to actuate the latch mechanism 100 from the front of the enclosure only while the front door of the enclosure is open. The latch mechanism 100 is activated by a temporary handle 160, such as a standard open box wrench or socket wrench. The latch mechanism 100 does not require a special handle or tool to connect the wall mount enclosure to the center section. The latch mechanism 100 will not interfere with the rack mounted equipment inside the enclosure when latching or unlatching the center section 60.

Furthermore, while the preferred embodiments of the present invention have been shown and described, it will be obvious to those skilled in the art that changes and modifications may be made without departing from the teaching of the invention. The matter set forth in the foregoing description and accompanying drawings is offered by way of illustration only and not as limitation. The actual scope of the invention is intended to be defined in the following claims when viewed in their proper perspective based on the prior art.

What is claimed is:

1. An enclosure for mounting electrical equipment, the enclosure comprising:
a wall mount section;
a center section pivotally attached to the wall mount section along one side; and
a latch mechanism securing the wall mount section to the center section, the latch mechanism is accessible only at a front of the enclosure, wherein the latch mechanism having a front latch support, a rear latch support, a cam latch and an actuation rod extending through the front latch support and the rear latch support and secured to the cam latch, whereby the latch mechanism secures the wall mount section to the center section.

2. The enclosure of claim 1, wherein actuation of the latch mechanism occurs outside of the center section of the enclosure.

3. The enclosure of claim 1, wherein a distal end of the actuation rod extends outside the center section of the enclosure, a temporary handle engages a distal end of the actuation rod to rotate the actuation rod and attached cam latch.

4. The enclosure of claim 1, wherein a socket wrench is positioned on a distal end of the actuation rod for rotating the latch mechanism between a latched position and an unlatched position.

5. The enclosure of claim 1, wherein the front latch support and the rear latch support are mounted to a side wall of the center section of the enclosure.

6. The enclosure of claim 1, wherein the front latch support has a base and two arms extending from the base, each arm of the front latch support having a rod opening for receiving the actuation rod, and the rear latch support has a base and two arms extending from the base, each arm of the rear latch support having a rod opening for receiving the actuation rod.

7. The enclosure of claim 1, wherein the cam latch has a base with arms extending from a side edge of the base, the base has a mounting opening for receiving a fastener, the arms have rod openings for receiving the actuation rod.

8. The enclosure of claim 7, wherein the cam latch further comprising a L-shaped connector extending from one of the arms.

9. The enclosure of claim 8, wherein the L-shaped connector has a first member that is parallel to the base of the cam latch and a second member that is parallel to the arms of the cam latch.

10. The enclosure of claim 9, wherein the L-shaped connector has a curved flange extending from an edge of the second member.

11. The enclosure of claim 6, wherein the cam latch is mounted between the arms of the rear latch support for preventing the cam latch from shifting out of position.

12. The enclosure of claim 1, wherein the cam latch is mounted to be positioned around the center section and to clamp against an inside of the wall mount section.
